(19) United States
(12) Patent Application Publication
(10) Pub. No.: US 2026/0013036 A1
(43) Pub. Date: Jan. 8, 2026

(54) WIRING BOARD

(71) Applicant: SHINKO ELECTRIC INDUSTRIES CO., LTD., Nagano (JP)

(72) Inventors: Tomoo YAMASAKI, Nagano (JP); Masaya TAKIZAWA, Nagano (JP)

(21) Appl. No.: 19/256,667

(22) Filed: Jul. 1, 2025

(30) Foreign Application Priority Data
Jul. 5, 2024 (JP) 2024-108595

(51) Int. Cl. H05K 1/02; H05K 1/11

(52) U.S. Cl. CPC H05K 1/0266; H05K 1/115

(57) ABSTRACT

A wiring board includes an interconnect layer including a metal pattern, and an insulating layer, disposed on the interconnect layer, and including a first resin pattern. The insulating layer includes a filler. The metal pattern includes a central region, and an outer region located on an outer periphery of the central region. The first resin pattern includes a first region covering the central region, and a second region covering a portion of the outer region and exposing other portions of the outer region. The metal pattern and the first resin pattern constitute an alignment mark.

### CROSS-REFERENCE TO RELATED APPLICATIONS

This application is based upon and claims priority to Japanese Patent Application No. 2024-108595, filed on Jul. 5, 2024, the entire contents of which are incorporated herein by reference.

### FIELD

Certain aspects of the embodiments discussed herein are related to wiring boards.

### BACKGROUND

For example, the build-up method is widely used as a technique for manufacturing a wiring board. According to the build-up method, insulating layers and interconnect layers are alternately stacked. In the wiring board manufactured by the build-up method, an upper interconnect layer needs to be accurately aligned in correspondence with a lower interconnect layer, by taking electrical connections between the layers into consideration. For this reason, an alignment mark serving as a reference for positioning the upper layer is formed in a portion of the lower interconnect layer. The alignment mark is optically read by a charged coupled device (CCD) camera or the like to perform an image recognition, and the upper layer is aligned with respect to the lower layer based on a result of the image recognition.

Japanese Laid-Open Patent Publication No. 2008-270768 is an example of the related art.

In the wiring board described above, in order to accurately align the upper layer with respect to the lower layer, it is necessary to correctly read the alignment mark.

### SUMMARY

Accordingly, it is an object in one aspect of the embodiments to provide a wiring board having an alignment mark that is less prone to a reading error.

According to one aspect of the embodiments, a wiring board includes an interconnect layer including a metal pattern; and an insulating layer, disposed on the interconnect layer, and including a first resin pattern, wherein the insulating layer includes a filler, the metal pattern includes a central region, and an outer region located on an outer periphery of the central region, the first resin pattern includes a first region covering the central region, and a second region covering a portion of the outer region and exposing other portions of the outer region, and the metal pattern and the first resin pattern constitute an alignment mark.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a partial plan view illustrating an example of a wiring board according to a first embodiment;

FIG. 2A and FIG. 2B are partial cross sectional views illustrating the example of the wiring board according to the first embodiment;

FIG. 3A, FIG. 3B, and FIG. 3C are cross sectional views illustrating an example of a method of forming an alignment mark;

FIG. 4 is a partial plan view illustrating an example of the alignment mark according to a first modification of the first embodiment;

FIG. 5 is a partial plan view illustrating an example of the alignment mark according to a second modification of the first embodiment;

FIG. 6 is a partial plan view illustrating an example of the alignment mark according to a third modification of the first embodiment;

FIG. 7 is a partial plan view illustrating an example of the alignment mark according to a fourth modification of the first embodiment;

FIG. 8 is a partial plan view illustrating an example of the alignment mark according to a fifth modification of the first embodiment;

FIG. 9 is a partial plan view illustrating an example of the alignment mark according to a sixth modification of the first embodiment; and

FIG. 10 is a partial plan view illustrating an example of the alignment mark according to a seventh modification of the first embodiment.

### DESCRIPTION OF EMBODIMENTS

Hereinafter, embodiments of the present invention will be described with reference to the accompanying drawings. In the drawings, those constituent elements that are the same are designated by the same reference numerals, and a redundant description of the same constituent elements may be omitted.

### First Embodiment

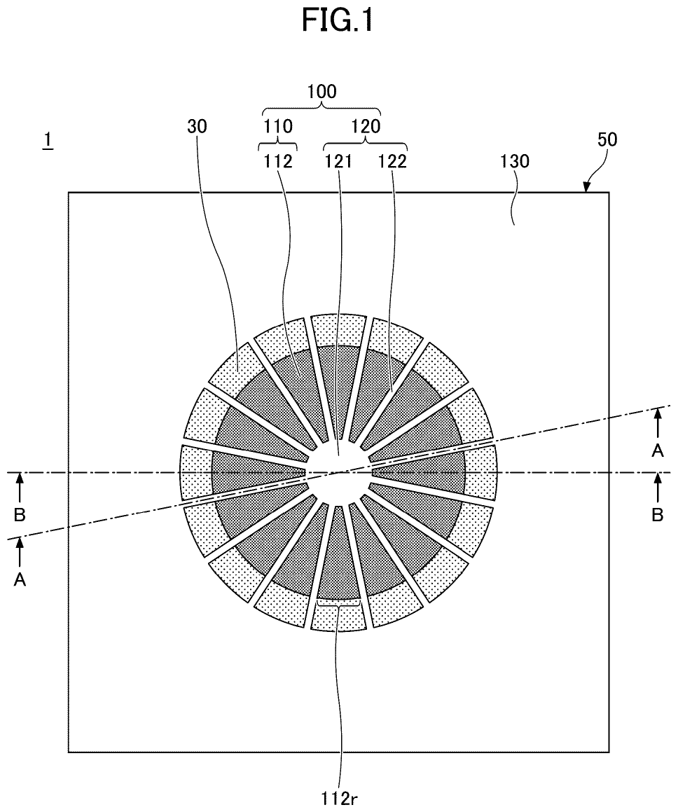

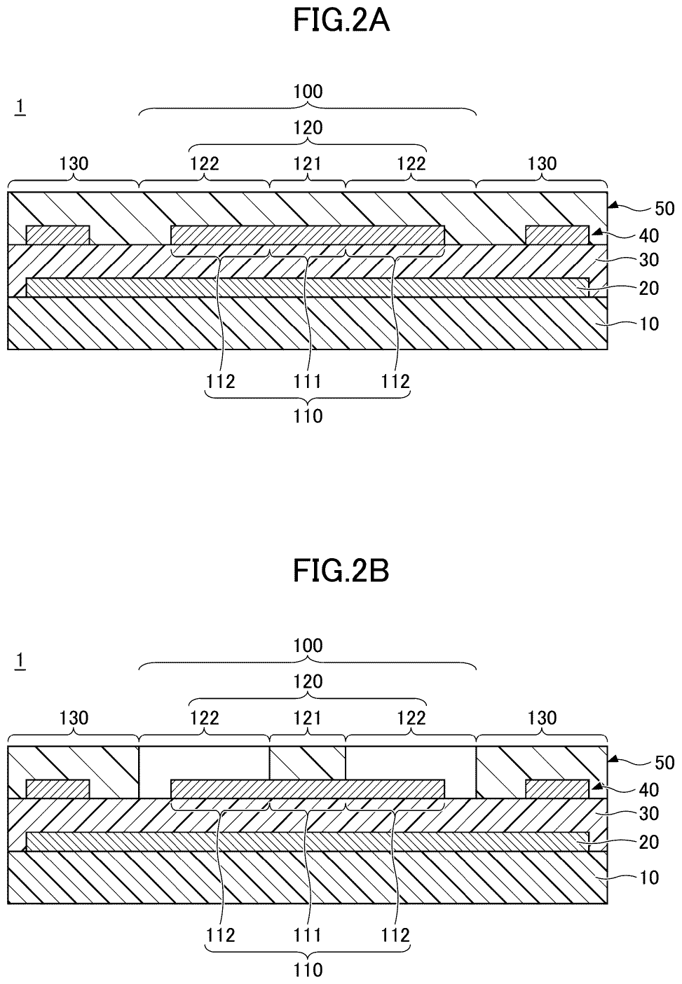

FIG. 1 is a partial plan view illustrating an example of a wiring board according to a first embodiment. FIG. 2A and FIG. 2B are partial cross sectional views illustrating the example of the wiring board according to the first embodiment. FIG. 2A illustrates a cross section taken along a line A-A in FIG. 1, and FIG. 2B illustrates a cross section taken along a line B-B in FIG. 1. FIG. 1, FIG. 2A, and FIG. 2B illustrate a vicinity of an alignment mark of a wiring board having an insulating layer and a interconnect layer.

As illustrated in FIG. 1, FIG. 2A, and FIG. 2B, a wiring board 1 includes an insulating layer 10, an interconnect layer 20, an insulating layer 30, an interconnect layer 40, and an insulating layer 50. The interconnect layer 20, the insulating layer 30, the interconnect layer 40, and the insulating layer 50 are successively stacked on the insulating layer 10. The wiring board 1 is a build-up board, for example. The wiring board 1 may include more insulating layers and interconnect layers.

The interconnect layer 40 includes a metal pattern 110. The interconnect layer 40 including the metal pattern 110 is formed on the insulating layer 30. The metal pattern 110 may be composed of copper (Cu), for example. A thickness of the metal pattern 110 may be in a range of approximately 10 μm to approximately 30 μm, for example. The metal pattern 110 has a circular shape in a plan view, for example. The metal pattern 110 includes a central region (or a central area) 111, and an outer region (or an outer area) 112 located on an outer periphery of the central region 111. The central region 111 may be an arbitrary region including a center of gravity of the metal pattern 110 in the plan view. The central region 111 has a circular shape in the plan view, for example.

The insulating layer 50 is disposed on the interconnect layer 40. A material used for the insulating layer 50 may be an insulating resin including an epoxy resin or a polyimide resin as a main component, for example. The insulating layer 50 includes a filler, such as silica (SiO₂) or the like. A thickness of the insulating layer 50 may be in a range of approximately 30 μm to approximately 40 μm, for example.

The insulating layer 50 includes a first resin pattern 120, and a second resin pattern 130. The first resin pattern 120 includes a first region 121 covering the central region 111 of the metal pattern 110, and a second region 122 covering a portion of the outer region 112 of the metal pattern 110 and exposing other portions of the outer region 112.

The first region 121 has a circular shape having a diameter smaller than that of the metal pattern 110 in the plan view. In this case, the diameter of the metal pattern 110 may be 500 μm, for example. Further, the diameter of the first region 121 may be 200 μm, for example. The second region 122 extends radially outward from an outer edge of the first region 121, for example. An outer edge of the outer region 112 of the metal pattern 110 is discretely exposed via the second region 122 of the first resin pattern 120.

The second resin pattern 130 is located outside the first resin pattern 120. The first region 121 of the first resin pattern 120 and the second resin pattern 130 are connected via the second region 122 of the first resin pattern 120. Hence, the second region 122 having a relatively small area in contact with the insulating layer 30 as a lower layer is connected to the first region 121 and the second resin pattern 130, thereby preventing delamination (or peeling) of the second region 122.

The metal pattern 110 and the first resin pattern 120 constitute an alignment mark 100. The alignment mark 100 can be optically read from an upper surface side of an insulating layer 50 using an exposure apparatus or the like. The alignment mark 100 can be used as a reference mark when aligning an upper layer with respect to the lower layer.

In a case where the outer edge of the outer region 112 of the metal pattern 110 is discretely exposed via the second region 122 of the first resin pattern 120, the exposure apparatus or the like complements a portion of the outer edge of the outer region 112 hidden by the second region 122. For this reason, even in a case where a portion of the outer edge of the outer region 112 is hidden by the second region 122 as illustrated in FIG. 1, the exposure apparatus or the like can recognize the shape of the outer edge of the outer region 112. In the example illustrated in FIG. 1, the exposure apparatus or the like can recognize the shape of the outer edge of the outer region 112 as being a circular shape.

In the alignment mark 100, the outer region 112 exposed via the second region 122 includes a plurality of radial regions 112r extending radially outward from the first region 121. Each radial region 112r may have an approximately fan-shape, for example. In the example illustrated in FIG. 1, 16 radial regions 112r are provided.

A length of an arc of each radial region 112r is preferably greater than a length of an arc of the second region 122 located between two adjacent radial regions 112r. In this case, when optically reading the outer edge of the outer region 112 using the exposure apparatus or the like, the portion of the outer edge of the outer region 112 hidden by the second region 122 can be complemented accurately, and it is possible to improve a readability of (or an ease of reading) the alignment mark 100.

In the illustrated example, the second region 122 of the first resin pattern 120 is connected to the second resin pattern 130 through the insulating layer 30, and a portion of the insulating layer 30 is exposed between the second resin pattern 130 and the outer edge of the outer region 112 of the metal pattern 110. A distance between the outer edge of the outer region 112 of the metal pattern 110 and an inner edge of the second resin pattern 130, that is, a length of the insulating layer 30 exposed in FIG. 1 in the radial direction of the metal pattern 110 may be in a range that is greater than or equal to 10 μm and less than or equal to 150 μm, for example.

Accordingly, because the outer edge of the outer region 112 and the inner edge of the second resin pattern 130 are separated from each other, the outer edge of the outer region 112 becomes clear, thereby improving the readability when the outer edge of the outer region 112 is optically read by the exposure apparatus or the like. In a case where there is no issue in reading when the outer edge of the outer region 112 is optically read by the exposure apparatus or the like, the outer edge of the outer region 112 and the inner edge of the second resin pattern 130 may be in contact with each other. In this case, the insulating layer 30 is not visible from the upper surface side of the insulating layer 50.

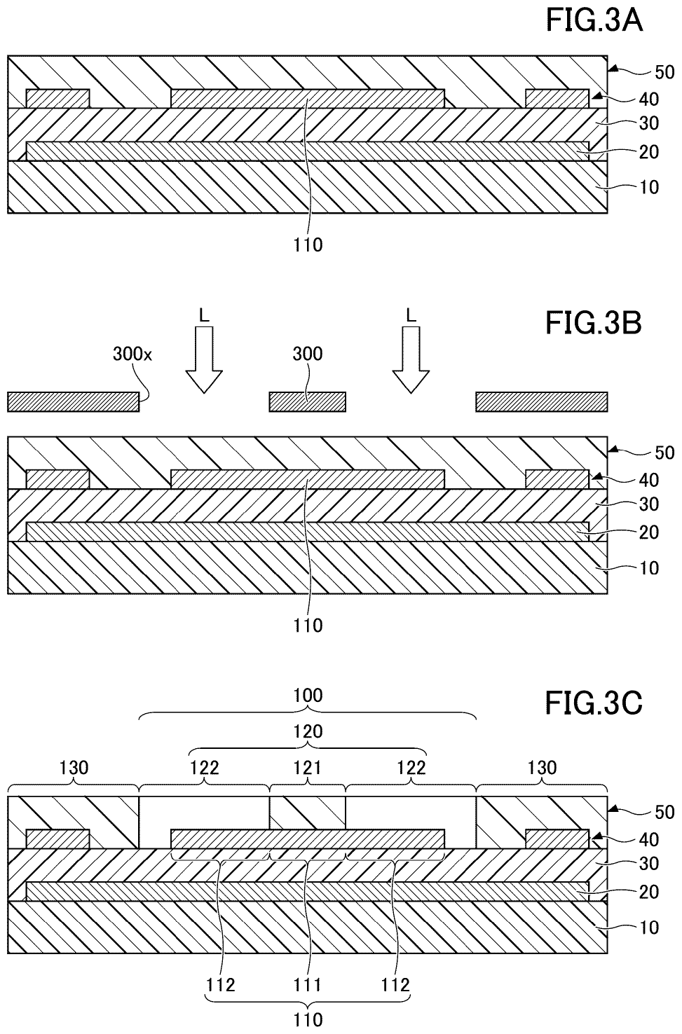

FIG. 3A, FIG. 3B, and FIG. 3C are cross sectional views illustrating a method for forming the alignment mark 100, and illustrate cross sections corresponding to the line B-B in FIG. 1.

When forming the alignment mark 100, first, as illustrated in FIG. 3A, the interconnect layer 20, the insulating layer 30, the interconnect layer 40, and the insulating layer 50 are successively stacked on the insulating layer 10. In this state, the metal pattern 110 separated from a peripheral region is formed in the interconnect layer 40. The metal pattern 110 is formed to a circular shape in the plan view, for example.

Next, as illustrated in FIG. 3B, a mask 300 having an opening 300x is disposed above the insulating layer 50. The opening 300x exposes a region of the insulating layer 50 to be removed. Then, the insulating layer 50 is irradiated with laser light L via the mask 300, and the insulating layer 50 exposed inside the opening 300x is removed. As a result, as illustrated in FIG. 3C, the alignment mark 100 can be formed. For example, an ultraviolet laser, such as an excimer laser or the like, which enables microfabrication, can be used to remove the insulating layer 50. The use of laser processing enabling the microfabrication is preferable in that a micro interconnect pattern can be fabricated during the same process (or step) as the formation of the alignment mark 100.

If an alignment mark that exposes the entire outer region 112 of the metal pattern 110 were to be formed, it would be necessary to remove the insulating layer 50 by continuously performing the laser processing on a region of the insulating layer 50 having a large area. Because the laser processing using the excimer laser employs a surface emission scanning method, when the region having the large area is continuously subjected to the laser processing, a filler such as silica or the like included in the insulating layer 50 aggregates into lumps and adheres to the alignment mark without being scattered. In a case where an outer edge of the alignment mark is hidden by the aggregated lumps, a reading error may easily occur when reading the alignment mark by the exposure apparatus or the like. The filler such as silica or the like cannot be processed by the excimer laser.

In contrast, in the alignment mark 100, the first resin pattern 120 covers a portion of the outer region 112 of the metal pattern 110, and includes the second region 122 exposing other portions of the outer region 112. That is, in the alignment mark 100, an entirety of the outer region 112 of the metal pattern 110 is not exposed. For this reason, in the insulating layer 50, a region having a large area does not need to be removed by a continuous laser processing, and a region having a small area is scanned a plurality of times. Accordingly, it is possible to reduce the area of the insulating layer 50 to be removed by one scan, and to prevent the aggregation of the filler included in the insulating layer 50. As a result, the outer edge of the alignment mark 100 will not be hidden by the aggregated lumps of the filler included in the insulating layer 50, and the alignment mark 100 is less prone to a reading error when reading the alignment mark 100 by the exposure apparatus or the like.

### Modifications of First Embodiment

In modifications of the first embodiment, an example of the alignment mark in which the shape of the second region 122 of the first resin pattern 120 covering the outer region 112 of the metal pattern 110 is different from that of the first embodiment will be described. In the modifications of the first embodiment, a redundant description of those constituent elements that are the same as the constituent elements of the first embodiment described above may be omitted.

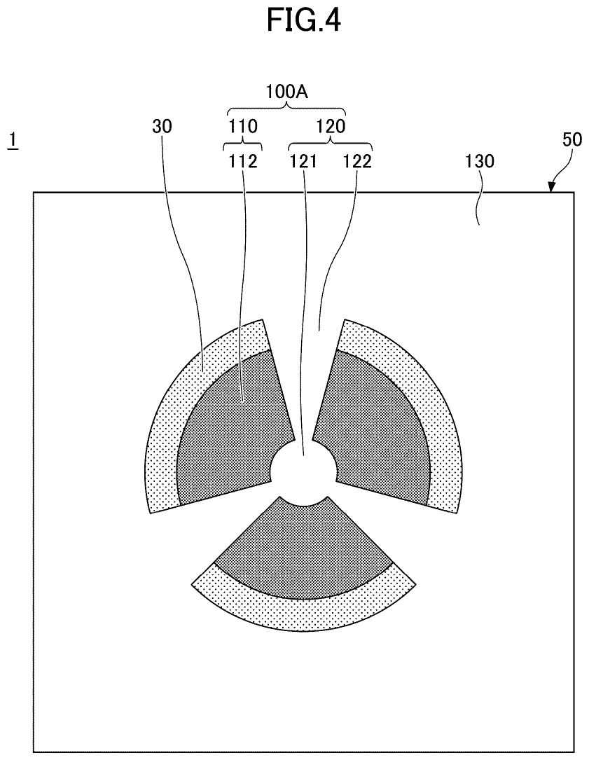

FIG. 4 is a partial plan view illustrating an example of the alignment mark according to a first modification of the first embodiment. In an alignment mark 100A illustrated in FIG. 4, the second region 122 of the first resin pattern 120 includes three sections. Each of the three sections has a width that widens from the side connected to the first region 121 toward the side connected to the second resin pattern 130. The outer region 112 of the metal pattern 110 is divided into three portions by the respective sections of the second region 122.

Accordingly, in the second region 122 of the first resin pattern 120, the sections dividing the area of the outer region 112 of the metal pattern 110 may have the same width as illustrated in FIG. 1, or may have a width that widens from the side connected to the first region 121 toward the side connected to the second resin pattern 130 as illustrated in FIG. 4. Effects similar to those obtainable in the first embodiment can also be obtained using the shape illustrated in FIG. 4.

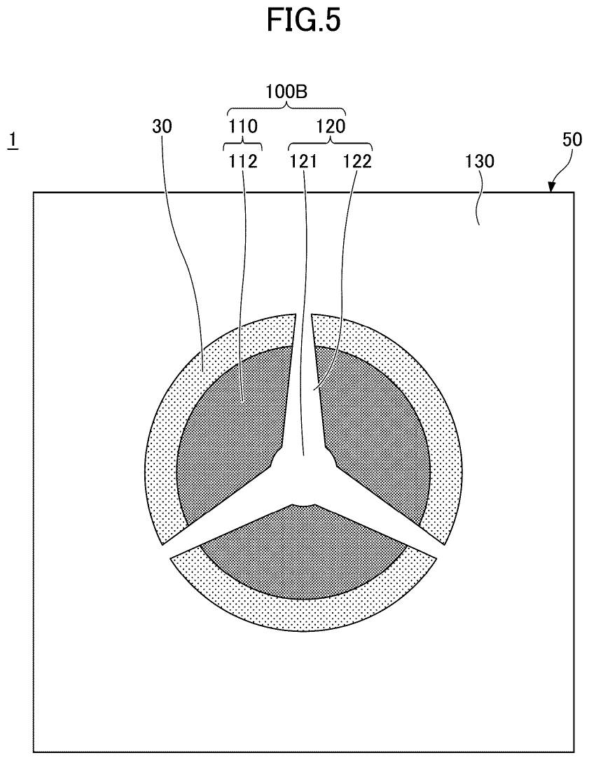

FIG. 5 is a partial plan view illustrating an example of the alignment mark according to a second modification of the first embodiment. In an alignment mark 100B illustrated in FIG. 5, the second region 122 of the first resin pattern 120 includes three sections. The width of each of the three sections narrows from the side connected to the first region 121 toward the side connected to the second resin pattern 130. The outer region 112 of the metal pattern 110 is divided into three portions by the respective sections of the second region 122.

Accordingly, in the second region 122 of the first resin pattern 120, the sections dividing the area of the outer region 112 of the metal pattern 110 may have a width that narrows from the side connected to the first region 121 toward the side connected to the second resin pattern 130. Effects similar to those obtainable in the first embodiment can also be obtained using the shape illustrated in FIG. 5. In the case of the shape illustrated in FIG. 5, a length of an arc of the outer edge of the outer region 112 of the metal pattern 110 that ends is shorter than that in the case of the shape illustrated in FIG. 4. For this reason, in the example illustrated in FIG. 5, the readability when the outer edge of the outer region 112 is optically read by the exposure apparatus or the like is improved when compared to the example illustrated in FIG. 4.

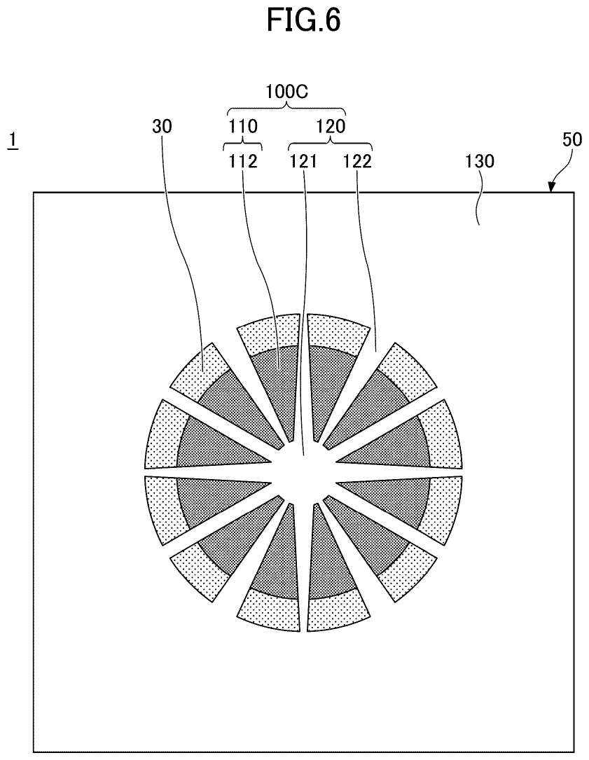

FIG. 6 is a partial plan view illustrating an example of the alignment mark according to a third modification of the first embodiment. In an alignment mark 100C illustrated in FIG. 6, the second region 122 of the first resin pattern 120 includes 12 section. Each of the 12 sections includes a portion having the same width, a portion having a width that widens from the side connected to the first region 121 toward the side connected to the second resin pattern 130, and a portion having a width that narrows from the side connected to the first region 121 toward the side connected to the second resin pattern 130. The outer region 112 of the metal pattern 110 is divided into 12 portions by the respective sections of the second region 122.

Accordingly, in the second region 122 of the first resin pattern 120, the sections dividing the area of the outer region 112 of the metal pattern 110 may include portions having different widths. Effects similar to those obtainable in the first embodiment can also be obtained using the shape illustrated in FIG. 6.

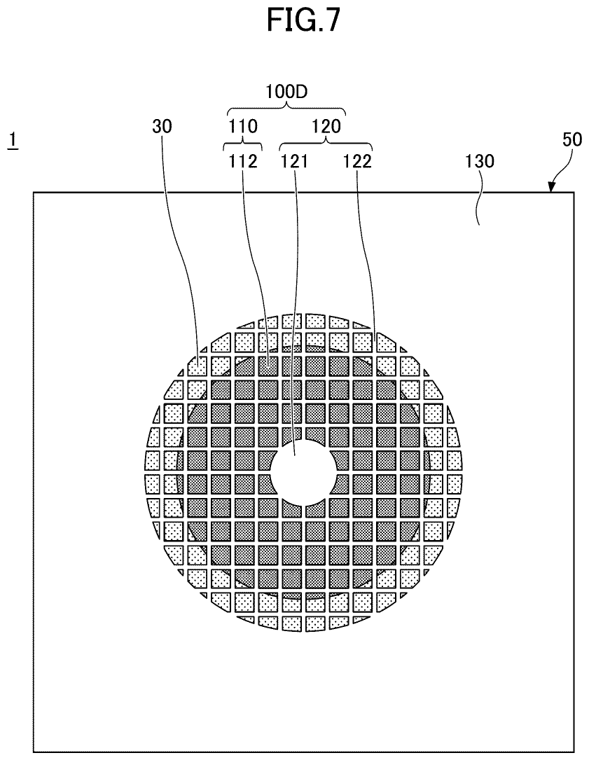

FIG. 7 is a partial plan view illustrating an example of the alignment mark according to a fourth modification of the first embodiment. In an alignment mark 100D illustrated in FIG. 7, the second region 122 of the first resin pattern 120 is formed in a lattice pattern (or a grid pattern). A spacing (or a grid width) of the lattice pattern may be constant, or may not be constant. For example, the spacing of the lattice pattern may increase or decrease in a specific direction.

Accordingly, even in the case where the second region 122 of the first resin pattern 120 is formed in the lattice pattern illustrated in FIG. 7, effects similar to those obtainable in the first embodiment can also be obtained.

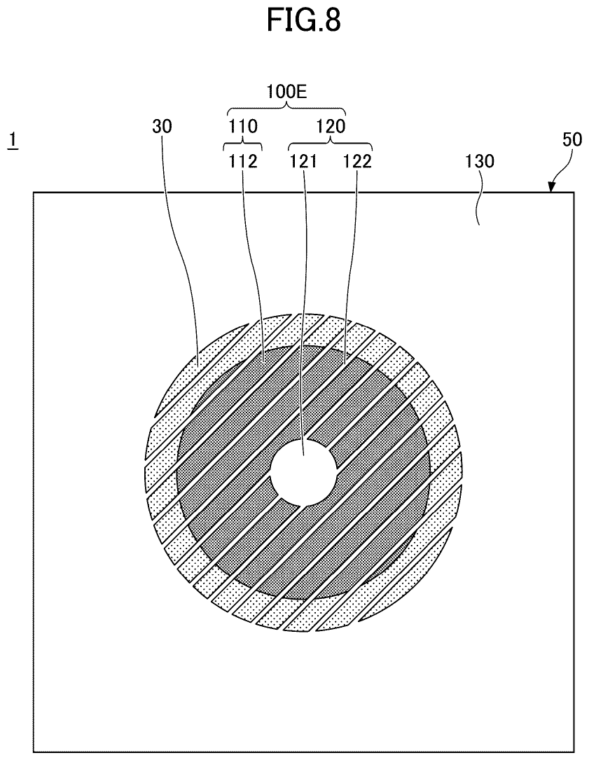

FIG. 8 is a partial plan view illustrating an example of the alignment mark according to a fifth modification of the first embodiment. In an alignment mark 100E illustrated in FIG. 8, the second region 122 of the first resin pattern 120 is formed in a pattern in which a plurality of sections extending linearly in the same direction are arranged in parallel at predetermined intervals. The plurality of sections may be inclined in any direction, as long as the sections are arranged in a pattern in which the plurality of sections are arranged in parallel at predetermined intervals. In addition, a width of each section of the plurality of sections may be constant, or may not be constant. For example, the width of each section of the plurality of sections may increase or decrease in a specific direction.

Accordingly, effects similar to those obtainable in the first embodiment can also be obtained in the case where the second region 122 of the first resin pattern 120 is formed in the pattern illustrated in FIG. 8 in which the plurality of sections extending linearly in the same direction are arranged in parallel at predetermined intervals.

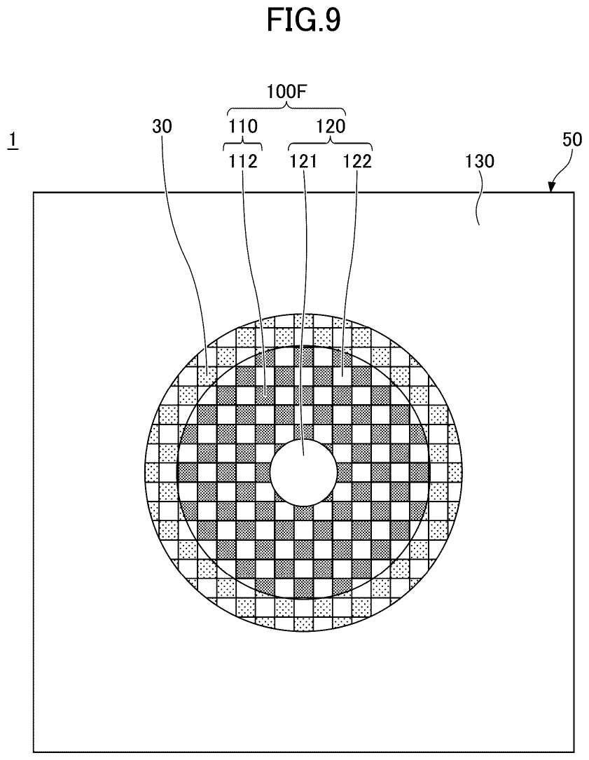

FIG. 9 is a partial plan view illustrating an example of the alignment mark according to a sixth modification of the first embodiment. In an alignment mark 100F illustrated in FIG. 9, the second region 122 of the first resin pattern 120 is formed in a checkerboard pattern. The second region 122 of the first resin pattern 120 includes a plurality of sections spaced apart from one another. The shape of each section of the plurality of sections spaced apart from one another may be a square shape or a rectangular shape. A length of one side of each section of the plurality of sections spaced apart from one another may be in a range of approximately 5 μm to approximately 15 μm, for example. By varying the area of each section of the plurality of sections spaced apart from one another, a ratio of the area of the portion where the first resin pattern 120 remains and the area of the portion where the first resin pattern 120 is removed can be freely varied on the outer region 112 of the metal pattern 110.

Accordingly, even in the case where the second region 122 of the first resin pattern 120 is formed in the checkerboard pattern illustrated in FIG. 9, effects similar to those obtainable in the first embodiment can also be obtained. When the second region 122 of the first resin pattern 120 is formed in the checkerboard pattern, a plurality of isolated island-shaped portions (or lands) that are not connected to the first region 121 and the second resin pattern 130 are present in the second region 122. For this reason, from a viewpoint of preventing delamination of the second region 122, the alignment marks 100 through 100E are more preferable than the alignment mark 100F. The second region 122 in which the plurality of island-shaped portions are arranged in the checkerboard pattern may have a structure in which the adjacent island-shaped portions are integrated at four corners thereof so as to prevent easy delamination of the second region 122.

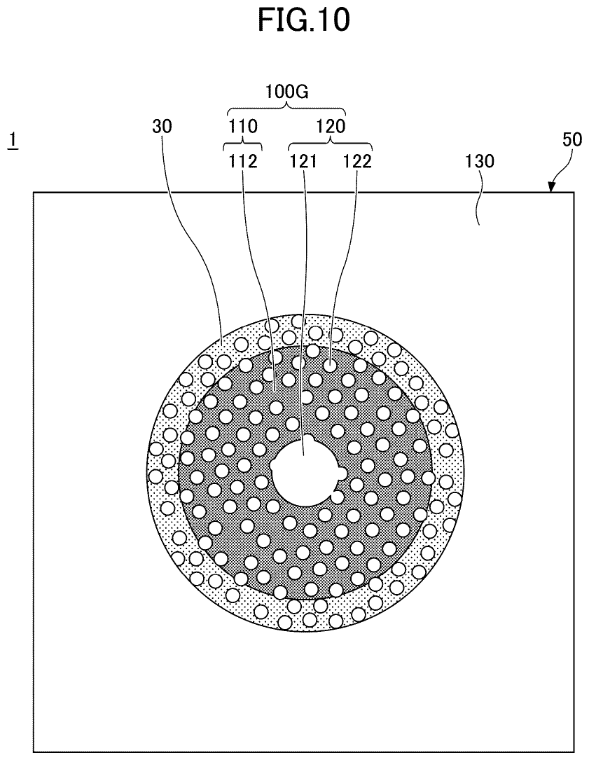

FIG. 10 is a partial plan view illustrating an example of the alignment mark according to a seventh modification of the first embodiment. In an alignment mark 100G illustrated in FIG. 10, the second region 122 of the first resin pattern 120 is formed in a dot pattern (or a polka-dot pattern). The second region 122 of the first resin pattern 120 includes a plurality of sections spaced apart from one another. The shape of each section of the plurality of sections spaced apart from one another may be a circular shape, an elliptical shape, or other shapes. By varying the area of each section of the plurality of sections spaced apart from one another, the ratio of the area of the portion where the first resin pattern 120 remains and the area of the portion where the first resin pattern is removed can be freely varied on the outer region 112 of the metal pattern 110.

Accordingly, even in the case where the second region 122 of the first resin pattern 120 is formed in the dot pattern illustrated in FIG. 10, effects similar to those obtainable in the first embodiment can also be obtained. In the case where the second region 122 of first resin pattern 120 is formed in the dot pattern, isolated portions that are not connected to the first region 121 and the second resin pattern 130 are present in the second region 122. For this reason, from a viewpoint of preventing delamination of the second region 122, the alignment marks 100 through 100E are more preferable than the alignment mark 100G.

According to the disclosed technique, it is possible to provide a wiring board having an alignment mark that is less prone to a reading error.

Although the modifications of the embodiments are numbered with, for example, “first,” “second,”, “third,” “fourth,” “fifth,” “sixth,” or “seventh,” the ordinal numbers do not imply priorities of the modifications of the embodiments. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A wiring board comprising:
an interconnect layer including a metal pattern; and
an insulating layer, disposed on the interconnect layer, and including a first resin pattern, wherein:
the insulating layer includes a filler,
the metal pattern includes a central region, and an outer region located on an outer periphery of the central region,
the first resin pattern includes a first region covering the central region, and a second region covering a portion of the outer region and exposing other portions of the outer region, and
the metal pattern and the first resin pattern constitute an alignment mark.

2. The wiring board as claimed in claim 1, wherein the outer region exposed via the second region includes a plurality of radial regions extending radially outward from the first region.

3. The wiring board as claimed in claim 2, wherein a length of an arc of each radial region of the plurality of radial regions is longer than a length of an arc of the second region located between two adjacent radial regions among the plurality of radial regions.

4. The wiring board as claimed in claim 1, wherein:
the insulating layer includes a second resin pattern located outside the first resin pattern, and
the first region and the second resin pattern are connected via the second region.

5. The wiring board as claimed in claim 4, wherein:
the metal pattern is formed on a second insulating layer,
the second region is connected to the second resin pattern through the second insulating layer,
a portion of the second insulating layer is exposed between the second resin pattern and an outer edge of the outer region.

6. The wiring board as claimed in claim 1, wherein an outer edge of the outer region is discretely exposed via the second region.

7. The wiring board as claimed in claim 1, wherein:
the metal pattern has a circular shape in a plan view, and
the first region has a circular shape having a diameter smaller than that of the metal pattern in the plan view.
